(19) United States
(12) Patent Application Publication
(10) Pub. No.: US 2011/0272368 A1
(43) Pub. Date: Nov. 10, 2011

(54) FRAME FOR MOUNTING SOLAR MODULES

(76) Inventor: Johann Kufner, Aholmnig (DE)

(21) Appl. No.: 13/097,945

(22) Filed: Apr. 29, 2011

(30) Foreign Application Priority Data
May 4, 2010 (DE) 20 2010 006 442.2

(51) Int. Cl. F24J 2/52; H01L 31/048

(52) U.S. Cl. 211/41.1

(57) ABSTRACT

A frame for jointly mounting at least two rectangular solar modules, wherein the frame comprises at least a group consisting of three parallel rails which are attached to a supporting structure at defined distances from each other,

characterized in that the middle rail of the three rails has a profile with flanges cantilevering towards both sides under which an edge of a solar module can be inserted, and that to the two outer rails of the three rails clamping elements can be bolted, by means of which solar modules inserted into the middle rail can be mounted on the two outer rails, namely on both respective edges which are adjacent to the edge inserted into the middle rail.

### BACKGROUND OF THE INVENTION

The invention relates to a frame for jointly mounting at least two rectangular solar modules on the frame, wherein said frame comprises at least a group consisting of three parallel rails which are mounted on a supporting structure at defined distances from each other.

DE 20 2005 001 469 U1 discloses a device for mounting solar modules on a roof surface on rails which are laid in the direction of the roof pitch and have open-top channels. It is possible to mount clampings in the channels by means of screws or bolts, which clampings wrap around the rims of the solar modules with a collar. The principle of this type of mounting is referred to as clamp mounting.

This type of mounting leads to a secure mounting of the solar modules on the rails. However, each clamping has to be bolted individually.

The object underlying the invention is to provide a frame or a mounting system, respectively, for solar modules, on which the solar modules can be mounted in a particularly rapid and cost-efficient manner, and which frame or mounting system nevertheless allows for a secure and weather-proof mounting.

### SUMMARY OF THE INVENTION

This object is achieved by a frame wherein the middle rail of the three rails of a group has a profile with flanges or collars cantilevering towards both sides, under each of which an edge of a solar module can be inserted. This type of mounting is referred to as insertion mounting. In contrast, clamping elements can be bolted to the two outer rails of the three rails, by means of which clamping elements the solar modules inserted into the middle rail can be mounted on the two outer rails, namely on the two respective edges which are adjacent to the edge inserted into the middle rail. This type of mounting is referred to as clamp mounting. “Edge” refers to one of the four sides of a rectangular solar module.

Thus, the invention is characterized in that the principles of insertion mounting and clamp mounting are combined. Although insertion mounting is basically faster, it is disadvantageous that the rails have to run parallel to two opposite edges, usually the narrow sides, of the solar modules. Consequently, the solar modules are held only at their outermost edges and, in the case of heavy snowfall, this might lead to a sagging of the modules. By contrast, by means of clamp mounting the rails can be located under the solar modules such that they are closer to their respective centers, which reduces sagging of the modules. The invention combines insertion mounting on one edge and clamp mounting on two edges adjacent to said edge, and, thus, combines the advantages of insertion mounting with those of clamp mounting.

The solar modules used can be usual, plate-shaped photovoltaic modules. Said modules are often rectangular in shape and have a size of about 80 cm×250 cm, for example, and, thus, often their length is substantially greater than their width. For this reason, the combination of insertion mounting and clamp mounting according to the invention is particularly advantageous since the solar modules cannot sag over their entire length.

According to a preferred embodiment the frame is designed such that the edge inserted into the middle rail forms the narrow side of the rectangular solar modules. “Narrow edge” refers to one of the two shorter sides of the rectangle. Advantageously, the respective distances between the three rails are each smaller than the length of the long sides of the rectangular solar modules. This means that the outer two of the three rails do not run close to the outer narrow sides, but closer to the center for a better support of the solar modules over their length in order to prevent a possible sagging in the case of snowfall.

Preferably, the distances between the three rails of a group are by approximately ⅓ to ⅛ shorter than the long side of a solar module. This means that the two outer rails support the solar modules at a distance of about ⅓ to ⅛ from the outer narrow sides. The inner narrow sides are inserted into the middle rail and, consequently, they are supported there. For a solar module having a length of approximately 1.5 m to 2.8 m this can mean that the outer rails run at a distance of about 30 cm-50 cm, preferably about 40 cm, from the outer narrow sides of the solar modules.

In detail, the middle rail preferably comprises a section which is T-shaped in profile, wherein under each of the flanges cantilevering towards both sides of the T an edge of a solar module can be inserted.

Preferably, the two outer rails have a different shape. In particular, they are designed such that corresponding clamping elements, by means of which the solar modules can be clamped, can be bolted thereto. According to a preferred embodiment the two outer rails have respective screw channels to which the clamping elements can be bolted. The clamping elements can be rim clamping elements by means of which one solar module can be mounted, or central clamping elements by means of which two adjacent solar modules can be mounted by means of one clamping element. For example, the outer rails or clamping elements, respectively, can be designed as is described in DE 20 2005 001 469 U1 or DE 20 2007 002 232 U1.

Preferably, the rails are oriented at least essentially horizontal. In particular, they may lie on an inclined plane, which preferably is directed towards the sun. Preferably, the rectangular solar modules are then inserted edgewise into the middle rail and clamped to the outer rails.

The supporting structure which carries the three rails can be a roof of a building or a movable elevation which can be readjusted to follow the azimuth angle of the sun. Preferably, however, it is a fixed elevation, i.e. a supporting structure which is directed towards the south and firmly anchored on the ground or on a rooftop.

The invention also relates to an above-described frame on which at least two, preferably more rectangular solar modules are mounted as has been described above.

These and other advantages of the invention will be further understood and appreciated by those skilled in the art by reference to the following written specifications, claims and appended drawings.

### BRIEF DESCRIPTION OF THE DRAWINGS

The invention is now explained in more detail with the help of an embodiment with reference to the appended drawings. The figures show:

FIG. 1 is a perspective view of a fixed elevation/support for solar modules having a frame according to the invention;

FIG. 2 is a top plan view of a frame according to the invention;

FIG. 3 is a cross-section through a middle rail;

FIG. 4 is a cross-section through an outer rail; and

FIG. 5 is a side view of an outer rail.

Identical parts in the figures are denoted with the same reference signs.

### DETAILED DESCRIPTION OF THE PREFERRED EMBODIMENTS

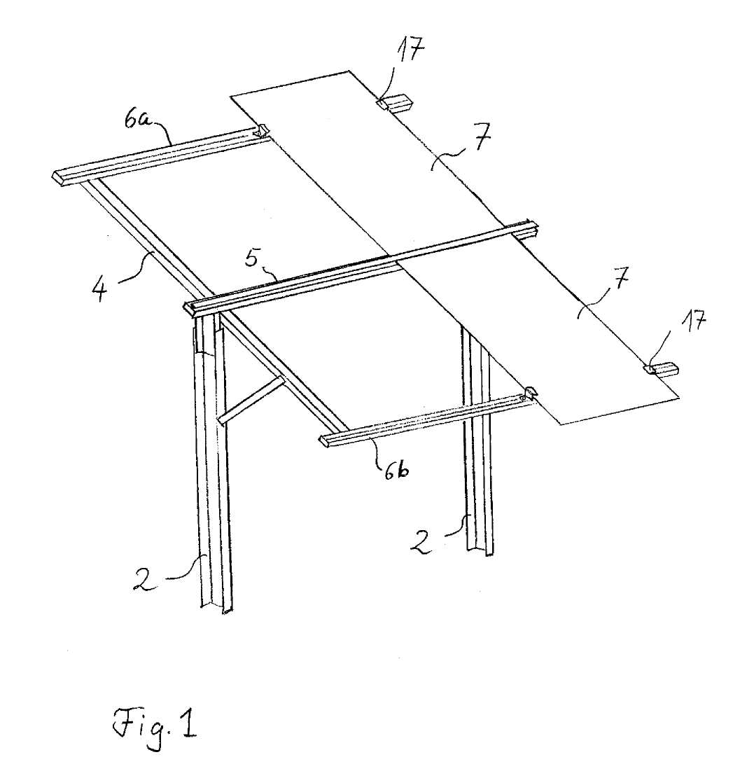

For purposes of description herein, the terms “upper,” “lower,” “right,” “left,” “rear,” “front,” “vertical,” “horizontal,” and derivatives thereof shall relate to the invention as oriented in FIG. 1. However, it is to be understood that the invention may assume various alternative orientations, except where expressly specified to the contrary. It is also to be understood that the specific devices and processes illustrated in the attached drawings, and described in the following specification are simply exemplary embodiments of the inventive concepts defined in the appended claims. Hence, specific dimensions and other characteristics relating to the embodiments disclosed herein are not to be considered as limiting, unless the claims expressly state otherwise.

FIG. 1 shows a fixed elevation for solar modules with posts 2 arranged in a row which are anchored in the ground, for example. To each post a so-called transverse beam 4 is attached, which is directed in the north-south direction and inclined towards the south at a suitable angle of inclination so as to achieve an optimal solar radiation onto the solar modules 7. On the transverse beams 4 three parallel rails 6a, 5, 6b are mounted which run parallel to each other and more or less horizontally in the direction of the row of posts 2. The rails form the core element of the frame according to the invention, on which frame a number of solar modules is mounted.

FIG. 1 shows only two solar modules 7; on a completely assembled solar system the frame is entirely covered with solar modules 7. Such a frame can extend over a long row of posts 2 with transverse beams 4, wherein each of the rails 5, 6a, 6b can extend over two or more posts 2.

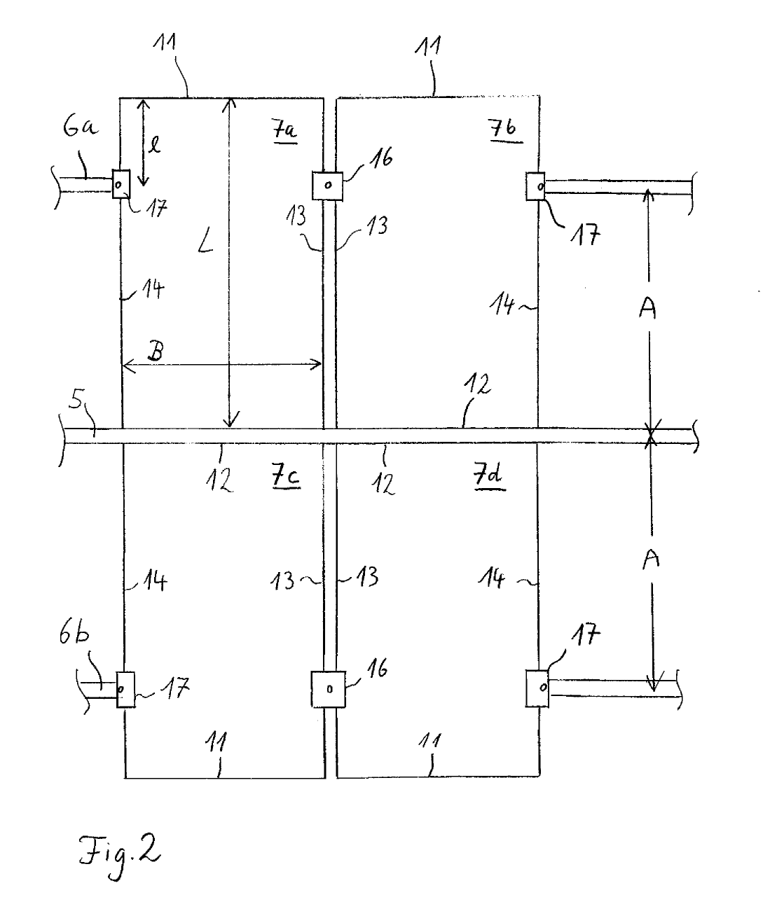

The middle rail 5 has a profile such that the solar modules 7 can be slid in or inserted with one of their respective edges, and they are then supported thereby. The solar modules 7 are supported on the outer rails 6a, 6b and are held there by means of the clamping elements 17 bolted to the rails 6. Since the solar modules are securely clamped by the clamping elements 17, they cannot slip out of the middle rail 5. The outer rails 6a and 6b support the solar modules 7 at a certain distance from their outer narrow sides. This will be explained in more detail with the help of the top view shown in FIG. 2.

FIG. 2 shows a schematic top view of a group of three rails 6a, 5 and 6b. Four solar modules 7a, 7b, 7c and 7d are inserted into this rail with their respective narrow sides 12 which face the middle rail 5. The solar modules 7 are rectangular and have a length L of typically 150-300 cm and a width of typically 60 cm-90 cm. Thus, the solar modules are rather elongate. In order to ensure that the modules are supported not only on their narrow sides 11, 12, the outer rails 6a, 6b run at a certain distance 1 from the outer narrow sides 11. Advantageously, this distance 1 is a substantial part of the length L of a solar module, for example between ⅓ and ⅛, preferably between ¼ and ⅙, for example about 40 cm. As a consequence, the solar modules 7 are optimally supported so that even in the case of heavy snowfall they will not sag. The solar modules are inserted into the middle rail 5 and are then bolted at two spots to the outer rails 6a, 6b by means of corresponding clamping elements 16, 17.

FIG. 2 shows two different types of clamping elements: where the rows 7a, 7b and 7c, 7d, respectively, of the solar modules end, a rim clamping element 17 is used. This element clamps the solar modules at their long sides 14.

Other clamping elements 16, the so-called “central” clamping elements, can be used at the long sides 13 which face each other. Said clamping elements make it possible to simultaneously mount two adjacent solar modules on one rail, preferably using only one screw or bolt. As a result, assembly is possible even faster and with even less effort.

Preferably, the distances A between the rails 6a and 5 and 5 and 6a, respectively, are equal and amount to L−1.

Thus, FIG. 2 shows two rows of solar modules, an upper row 7a, 7b and a lower row 7c, 7d. The upper row is inserted into the middle rail 5 with its lower narrow sides 12, and the lower row is inserted with its upper narrow sides 12. As a matter of course, each row typically comprises not only two but a larger number of solar modules arranged adjacent to each other.

FIG. 3 shows an exemplary cross-section through a middle rail 5. The middle rail 5 is an aluminum profile, for example, having a central bar 20 at the upper end of which two flanges 21, 22 which cantilever towards the sides are arranged. Said flanges wrap around the edges 11 of the solar modules 7a and 7c, which are also shown in cross-section.

Towards the bottom, the solar modules 7 are supported by corresponding bulges 23, 24, for example made of aluminum, but also of plastic or rubber, so that the solar modules are not damaged when they are inserted between the flange 21 and the bulge 23 or between the flange 22 and the bulge 24, respectively. The bulges 23, 24 can also be formed as separate parts which can be manufactured in different heights and laid onto the middle rail 5. This makes it possible to employ solar modules of different heights.

As a matter of course, different other designs of the middle rail 5 are also suitable for inserting the solar modules 7 from the left or from the right (in the illustration of FIG. 3).

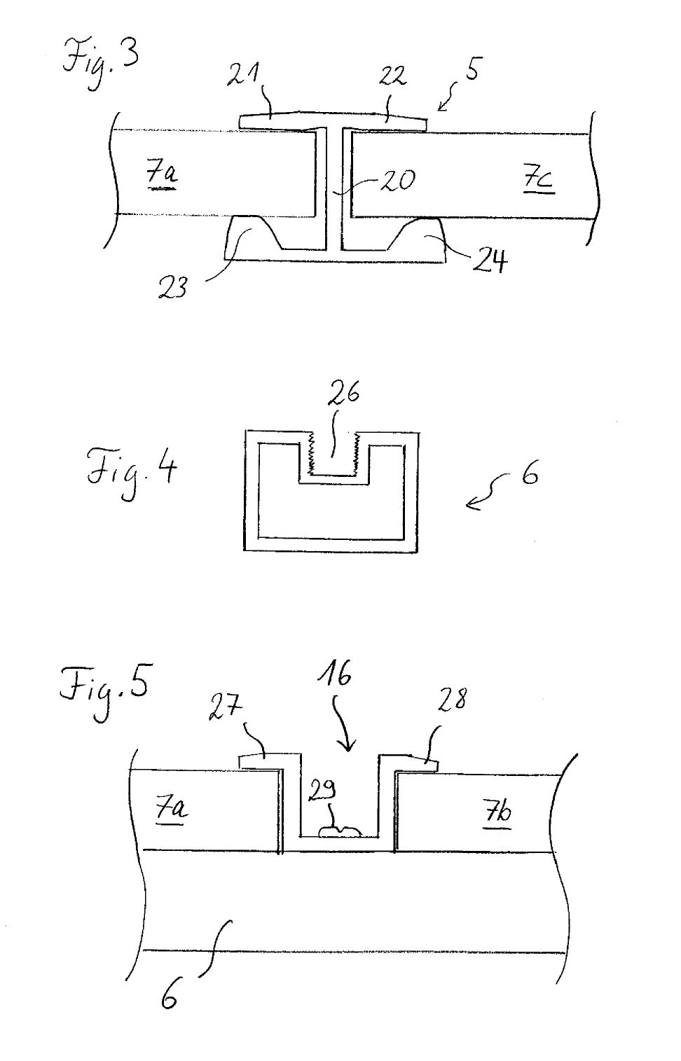

FIG. 4 shows a simple embodiment of a cross-section of an outer rail 6. This can also be an aluminum profile having a screw channel 26. The screw channel 26 makes it possible to use a screw or bolt at any desired spot along the length of the profile 6 in order to attach a clamping element 16, 17 and, thus, to mount a solar module 7.

FIG. 5 shows a rail 6 with solar modules 7a and 7b held thereon from the side or in a bottom view of FIG. 2. The rail 6 runs horizontally from left to right. Transversely to the rail 6 a central clamping element 16 is put on which comprises a profile section with a profile which is more or less U-shaped. Towards the ends of the side legs of the U there are again flanges 27, 28 which wrap around the edges 13 of solar modules 7a and 7b, for example, and frictionally clamp said modules against the rail 6. The clamping element 16 is attached to the screw channel 26 of the rail 6 by means of a screw 29, only the head of which can be seen in FIG. 5.

The invention provides for a particularly advantageous hybrid mounting which comprises both elements of an insertion technique as well as of clamp mounting on several rails which are arranged parallel to each other. A supporting structure can comprise one group as well as several groups of three rails each.

In the foregoing description, it will be readily appreciated by those skilled in the art that modifications may be made to the invention without departing from the concepts disclosed herein. Such modifications are to be considered as included in the following claims, unless these claims by their language expressly state otherwise.

1-10. (canceled)

11. A frame for jointly mounting at least two rectangular solar modules, comprising:
a frame that includes a first outer rail, a middle rail and a second outer rail which are attached to a supporting structure at defined distances from each other, wherein the middle rail has a profile with flanges cantilevering towards both sides under which a first edge of a solar module can be inserted, and wherein clamping elements are adapted to secure a second edge of the solar module adjacent to the first edge of the solar module to the first and second outer rails.

12. The frame according to claim 11, wherein the solor panel is rectangularly shaped, and wherein the first edge inserted into the middle rail forms a narrow side of the solar module.

13. The frame according to claim 12, wherein a distance between the middle rail and either of the outer rails is less than or equal to an overall length of the solar module.

14. The frame according to claim 13, wherein a distance between the middle rail and either of the outer rails is between about ⅓ to about ⅛ shorter than the overall length of the solar module.

15. The frame according to claim 14, wherein the middle rail includes a T-shaped profile defining the flanges cantilevering towards both sides of the T-shaped profile, and under which the first edge of the solar module can be inserted.

16. The frame according to claim 15, wherein each of the two outer rails included a screw channel to which the clamping elements are bolted.

17. The frame according to claim 16, wherein the clamping elements each comprise at least one of a rim clamping element and a central clamping element.

18. The frame according to claim 16, wherein the outer rails and the middle rail are oriented substantially horizontal.

19. The frame according to claim 18, wherein the outer rails and the middle rail lie in an inclined plane.

20. The frame according to claim 19, wherein the supporting structure includes at least one of a roof, a movable elevation, and a fixed elevation.

21. The frame according to claim 11, wherein a distance between the middle rail and the either of the outer rails is less than or equal to an overall length of the solar module.

22. The frame according to claim 21, wherein a distance between the middle rail and either of the outer rails is between about ⅓ to about ⅛ shorter than the overall length of the solar module.

23. The frame according to claim 11, wherein the middle rail includes a T-shaped profile defining the flanges cantilevering towards both sides of the T-shaped profile, and under which the first edge of the solar module can be inserted.

24. The frame according to claim 11, wherein each of the two outer rails included a screw channel to which the clamping elements are bolted.

25. The frame according to claim 11, wherein the clamping elements each comprise at least one of a rim clamping element and a central clamping element.

26. The frame according to claim 11, wherein the outer rails and the middle rail are oriented substantially horizontal.

27. The frame according to claim 26, wherein the outer rails and the middle rail lie in an inclined plane.

28. The frame according to claim 11, wherein the supporting structure includes at least one of a roof, a movable elevation, and a fixed elevation.
